(19) United States
(12) Patent Application Publication
(10) Pub. No.: US 2003/0113952 A1
(43) Pub. Date: Jun. 19, 2003

(54) Underfill materials dispensed in a flip chip package by way of a through hole

(76) Inventors: Mahesh Sambasivam, Chandler, AZ (US); Vassoudevane LeBonheur, Tempe, AZ (US)

Correspondence Address: BLAKELY SOKOLOFF TAYLOR & ZAFMAN, 12400 WILSHIRE BOULEVARD, SEVENTH FLOOR, LOS ANGELES, CA, 90025, US

(21) Appl. No.: 10/033,854

(22) Filed: Dec. 19, 2001

(51) Int. Cl. H01L 21/44; H01L 21/48; H01L 21/50

(52) U.S. Cl. 438/108; 438/613; 438/126; 438/127

(57) ABSTRACT

A microelectronic device and methods of fabricating the same comprising disposing an underfill material between a substrate and a flip chip by providing a hole through the substrate wherein the underfill material is injected therethrough.

### BACKGROUND OF THE INVENTION

1. Field of the Invention

The present invention relates to methods for dispensing underfill materials during microelectronic package fabrication and the microelectronic packages resulting from the same. In particular, the present invention relates to injecting an underfill material through a hole in a substrate that supports a flip chip within the microelectronic package.

2. State of the Art

In the field of electronic systems, there is continuous competitive pressure to increase the performance of components while reducing production costs. This competitive pressure is particularly intense in the fabrication of microelectronic devices, where each new generation must provide increased performance while also reducing the size or footprint of the microelectronic device.

As shown in FIG. 12, an exemplary microelectronic package includes a microelectronic die 202 that is mounted on a substrate 204, such as an interposer, a motherboard, and the like, which functionally connects the microelectronic die 202 through a hierarchy of electrically conductive paths (not shown) to the other electronic components (not shown). The illustrated method for electronically mounting the microelectronic die 202 to the substrate 204 is called flip chip bonding. This includes solder bumps or balls (leaded and unleaded), stud bump, and polymer bump interconnection. In this mounting method, electrically conductive terminals or pads 206 on an active surface 208 of the microelectronic die 202 are attached directly to corresponding lands 212 on a surface 214 of the substrate 204 using reflowable solder bumps or balls 216 (shown), thermocompression bonding, or any other known methods of flip chip attachment.

To enhance the reliability of the solder bumps 216 connecting the microelectronic die pads 206 and the substrate lands 212, an underfill material is used to mechanically and physically reinforce them. In a known method of underfill encapsulation shown in FIGS. 13 and 14, a low viscosity underfill material 222, such as an epoxy material, is dispensed from at least one dispensing needle 230 along at least one edge 224 (usually one or two edges) of the microelectronic die 202. The underfill material 222 is drawn between the microelectronic die 202 and the substrate 204 by capillary action (in generally the x-direction shown as arrows 240 in FIG. 14), and the underfill material 222 is subsequently cured (hardened) using heat, which forms the microelectronic package 200 shown in FIG. 15.

With the pressure to decrease the size of the microelectronic packages, bump pitch 226 and bump height 228 has decreased. Bump pitches 226 are currently between 100 and 300 μm, and bump height 228 are currently between 50-150 μm. Thus, it has become successively more difficult to obtain adequate underfill material dispersion without continuously deceasing the viscosity of the underfill material 222 or improving its wettability properties. However, decreasing the viscosity and/or improving the wettability of the underfill material 222 results in the underfill material 222 bleeding out and substantially surrounding the microelectronic die 202, as shown in FIGS. 15 and 16. This bleedout area beyond the edges 224 of the microelectronic die 202 is generally referred to as the “underfill tongue” 232 and may be about 2-5 mm wide 234. The underfill tongue 232 is a problem because it covers and contaminates valuable surface area on the substrate 204.

For example, as shown in FIG. 17, a exemplary stacked package 250 includes a microelectronic die 202 that is mounted on a substrate 204 with a plurality of solder bumps 216 extending between microelectronic die pads 206 and substrate lands 212, as discussed with regard to FIG. 12. A second microelectronic die 242 is attached by its back surface 244 to a back surface 246 of the microelectronic die 202 with a layer of adhesive 248. A plurality of wirebonds 252 makes electrical contact between lands 254 on an active surface 256 of the second microelectronic die 242 and wirebond lands 258 on the substrate 204. The substrate wirebond lands 258 are placed as close to the microelectronic die 202 as possible (currently about 1 mm therefrom) in order to conserve the valuable surface area in the substrate 204 and also meet chip scale package small form factor requirements. However, FIG. 17 illustrates the stacked package 250 without an underfill material. As shown in FIG. 18, the underfill material 222 is disposed before the wirebonds 252 (see FIG. 17) are attached. However, the underfill tongue 232 extends 2-5 mm wide 234, which covers the wirebond lands 258. Thus, at least the portion of the underfill tongue 232 covering the wirebond lands 258 would have to be removed in order to attach the wirebonds 252 (see FIG. 17). This, of course, is difficult and may reduce the reliability of the microelectronic device, as well as increasing the package cost.

Although techniques such molding processes have been tried with limited success, there is currently no reasonable solution to the underfill tongue problem. Therefore, it would be advantageous to develop apparatus and techniques to effectively dispose underfill material between a microelectronic die and the substrate while substantially reducing the underfill tongue.

### BRIEF DESCRIPTION OF THE DRAWINGS

While the specification concludes with claims particularly pointing out and distinctly claiming that which is regarded as the present invention, the advantages of this invention can be more readily ascertained from the following description of the invention when read in conjunction with the accompanying drawings in which:

FIG. 1 is a side cross-sectional view of a substrate, according to the present invention;

FIG. 2 is a side cross-sectional view of the substrate of FIG. 1 having a through-hole therein, according to the present invention;

FIG. 3 is a side cross-sectional view of the substrate of FIG. 2 having a microelectronic die electrically coupled thereto, according to the present invention;

FIG. 4 is a side cross-sectional view of the structure of FIG. 3 inverted, according to the present invention;

FIG. 5 is a side cross-sectional view of the structure of FIG. 4 wherein a dispensing needle disposes an underfill material between the substrate and the microelectronic die through the through-hole, according to the present invention;

FIG. 6 is a top plan view along lines 6-6 of FIG. 5, according to the present invention;

FIG. 7 is a side cross-sectional view of the structure of FIG. 5 after curing of the underfill material, according to the present invention;

FIG. 8 is a side cross-sectional view of the structure of FIG. 3 wherein a dispensing needle disposes an underfill material between the substrate and the microelectronic die through the through-hole, according to the present invention;

FIG. 9 is a side cross-sectional view of a structure similar to the structure of FIG. 7 wherein the substrate includes wirebond lands, according to the present invention;

FIG. 10 is a side cross-sectional view of the structure of FIG. 9, wherein a second microelectronic die is attached by a back surface to a back surface of the microelectronic die, according to the present invention;

FIG. 11 is a side cross-sectional view of the structure of FIG. 10 having wirebonds electrically connecting bond pads on an active surface of the second microelectronic die to the substrate wirebond lands, according to the present invention;

FIG. 12 is a side cross-section view of a microelectronic die attached to a substrate, as known in the art;

FIG. 13 is a side cross-sectional view of a needle dispensing an underfill material proximate a side of the microelectronic die of FIG. 11, as known in the art;

FIG. 14 is a top plan view of the structure of FIG. 13 along line 14-14 of FIG. 13, as known in the art;

FIG. 15 is a side cross-sectional view of the structure of FIG. 12 after the underfill material had been dispensed, as known in the art;

FIG. 16 is a top plan view of the structure of FIG. 15 along line 16-16 of FIG. 15, as known in the art;

FIG. 17 is a side cross-sectional view of the structure of FIG. 12, wherein a second microelectronic die attached by a back surface to a back surface of the microelectronic die and having wirebonds electrically connecting bond pads on an active surface of the second microelectronic die to the substrate wirebond lands, as known in the art; and

FIG. 18 is a side cross-sectional view of the structure of FIG. 12, wherein a second microelectronic die attached by a back surface to a back surface of the microelectronic die and having an underfill material disposed between the microelectronic die and the substrate, as known in the art.

### DETAILED DESCRIPTION OF THE ILLUSTRATED EMBODIMENT

In the following detailed description, reference is made to the accompanying drawings that show, by way of illustration, specific embodiments in which the invention may be practiced. These embodiments are described in sufficient detail to enable those skilled in the art to practice the invention. It is to be understood that the various embodiments of the invention, although different, are not necessarily mutually exclusive. For example, a particular feature, structure, or characteristic described herein, in connection with one embodiment, may be implemented within other embodiments without departing from the spirit and scope of the invention. In addition, it is to be understood that the location or arrangement of individual elements within each disclosed embodiment may be modified without departing from the spirit and scope of the invention. The following detailed description is, therefore, not to be taken in a limiting sense, and the scope of the present invention is defined only by the appended claims, appropriately interpreted, along with the full range of equivalents to which the claims are entitled. In the drawings, like numerals refer to the same or similar functionality throughout the several views.

The present invention relates to forming a microelectronic device disposing an underfill material between a substrate and a flip chip by providing a through-hole through the substrate, wherein the underfill material is delivered through the though-hole.

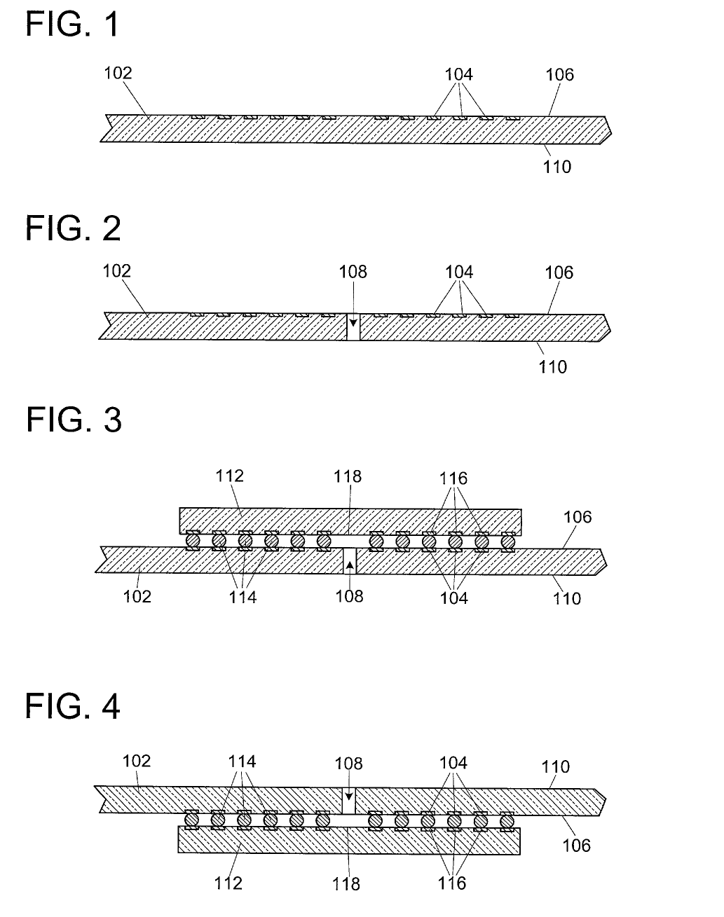

FIGS. 1-7 illustrate a method of forming an exemplary microelectronic device. FIG. 1 illustrates a substrate 102, such as a motherboard, interposer, or the like, including a plurality of lands 104 disposed on a first surface 106 thereof. The substrate lands 104 are connected to a hierarchy of electrical conductive paths (not shown) to other electronic components (not shown) to provide electrical connection thereto with a subsequently mounted microelectronic die. As shown in FIG. 2, a through-hole 108 is formed through the substrate 102 extending from the substrate first 106 to an opposing second surface 110. A via or through-hole 108 may be formed by any method known in the art, including, but not limited to drilling, laser ablation, etching, and the like. The through-hole 108 may be formed during the fabrication of the substrate 102, such as during the fabrication of through-hold vias and be plated or non-plated, as will be understood by those skilled in the art. It is, of course, understood that multiple methods could be used to form the through-hole 108. For example, the structure 102 could comprise a core wherein a hole is drilled therethrough. Trace metallization/dielectric layers could be formed on the core and a laser ablation could be used to form a hole through the trace metallization/dielectric layers to meet up with the hole in the core.

As shown in FIG. 3, a microelectronic die 112 is electronically mounted on the substrate 102. The illustrated method for electronically mounting the microelectronic die 112 to the substrate 102 is the attachment methods previously discussed. Electrically conductive terminals or lands 116 on an active surface 118 of the microelectronic die 112 are attached directly to the corresponding substrate lands 104 using conductive bumps or balls 114, such as leaded or lead-free reflowable solders ball (preferred), leaded or lead-free solder paste, metal filled epoxy, and the like. The resulting structure is then flipped, as shown in FIG. 4, to expose the through-hole 108 from the substrate second surface 110. This flipping of the structure places the structure in an orientation such that the microelectronic die 112 is gravitationally below the substrate 102. In other word, gravity pulls toward the microelectronic die 112 relative to the substrate 102.

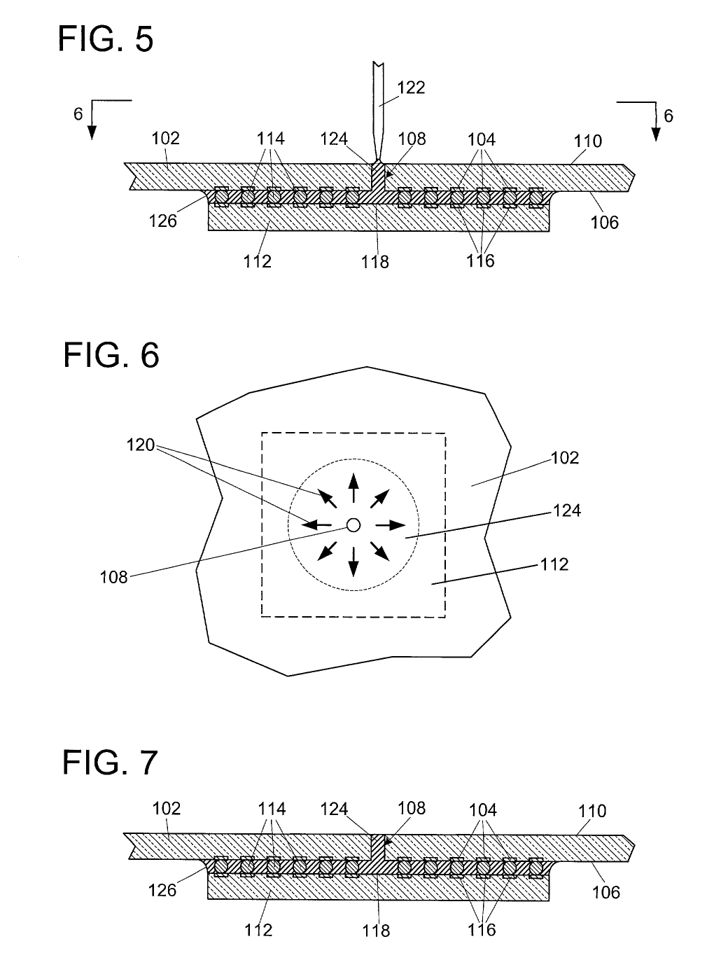

An underfill dispensing tool 122, such as a dispense needle, is positioned in or proximate to the through-hole 108 and an underfill material 124 is dispensed through the underfill dispensing tool 122 and into the through-hole 108, as shown in FIG. 5. The underfill material 124 may include, but is not limited to the following chemistries, epoxies (preferred), cyanate esters, silicones, and the like. Typically, the underfill materials contain reinforcing particles, such as silica (preferred), alumina, or Teflon®.

As shown in FIG. 6, capillary action distributes the underfill material 124 substantially evenly in all directions (illustrated by arrows 120) during injection. As further shown in FIG. 5, the underfill material 124 flows around the conductive bumps 114 and forms a fillet 126 proximate edges 128 of the microelectronic die 112. The combination of the gravity pulling the underfill material 124 toward the microelectronic die 112 and the inherent surface tension of the underfill material 124 will restrict the flow of the underfill material 124 proximate the microelectronic die edges 128. Thus, this process substantially reduces underfill tongue. It is, of course, understood that the through-hole 108 should be positioned in relation to the pattern of the conductive balls 114 such that the underfill material 124 distributes itself substantially evenly. Furthermore, it is preferred that a predetermined amount of underfill material 124 be used, as an excess amount may overcome the surface tension at the fillet 126, causing the underfill material 124 to drip.

The underfill dispensing tool 122 is withdrawn and the underfill material 124 is then cured (usually heated to solidify the underfill material), resulting in the microelectronic package 130, as shown in FIG. 7. It is preferred that the conductive bumps or balls 114 are reflowed for attachment prior to dispensing the underfill material. However, it is understood that the reflow (if necessary) of conductive bumps or balls 114 for the attachment of the microelectronic die 112 would also be achieved simultaneously with the curing of the underfill material 124. Furthermore, although the underfill material 124 is preferably curing while inverted, it may be cured in any position.

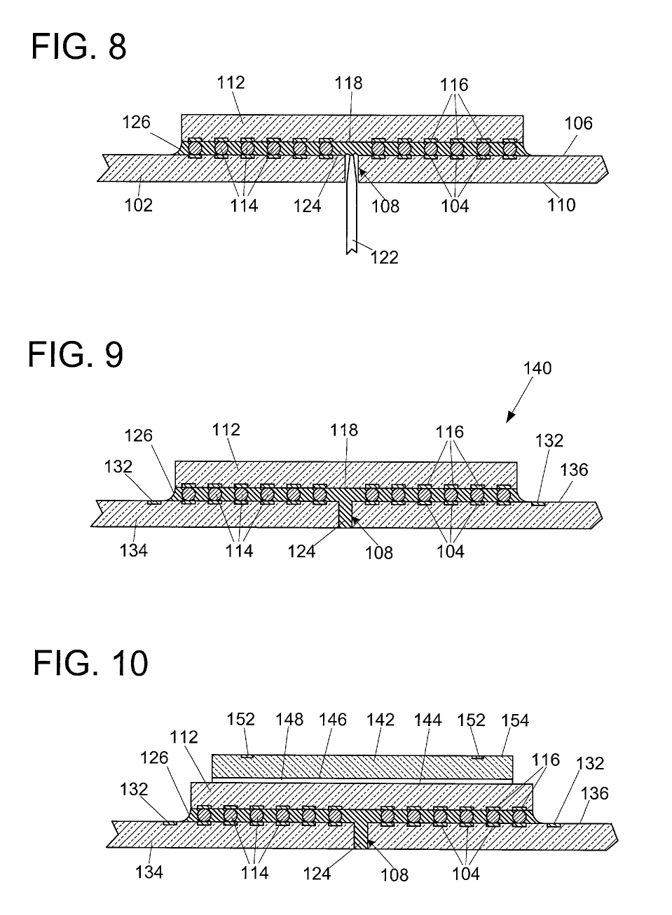

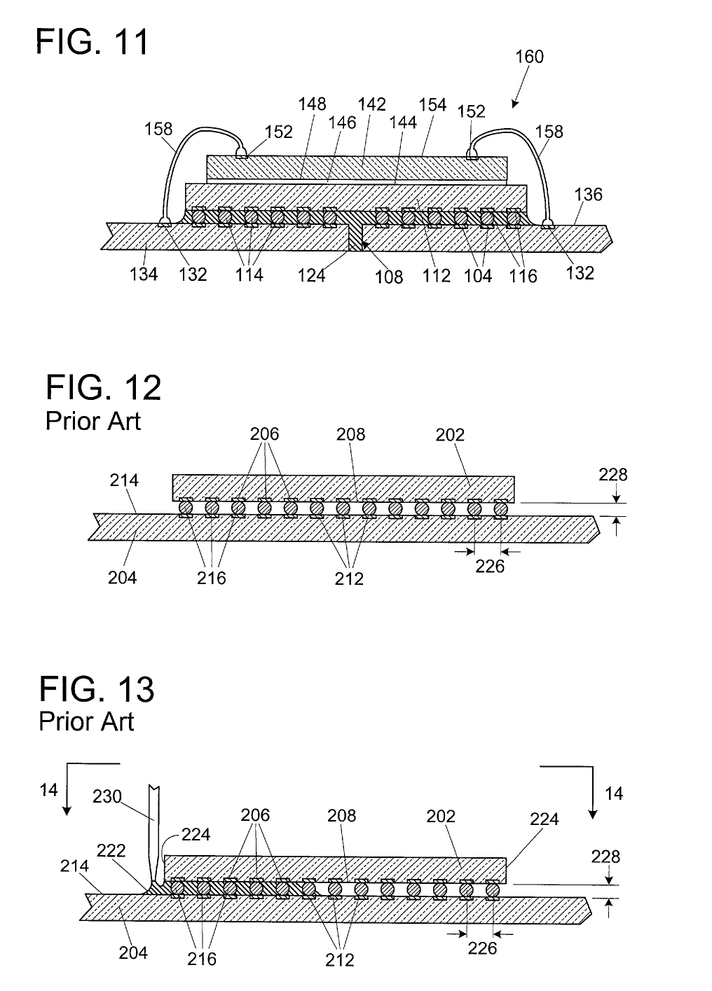

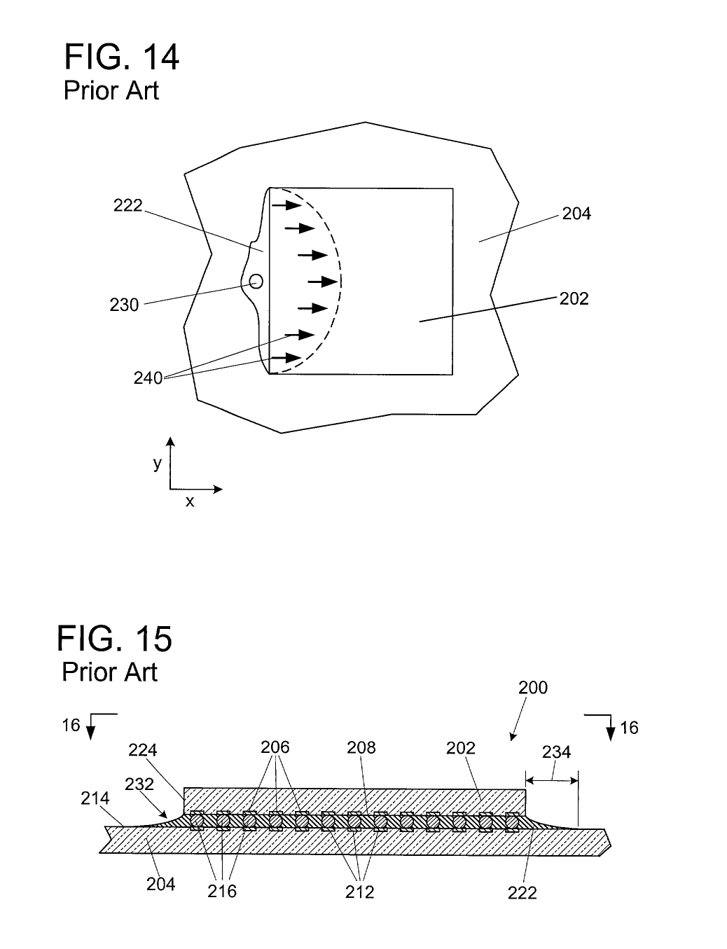

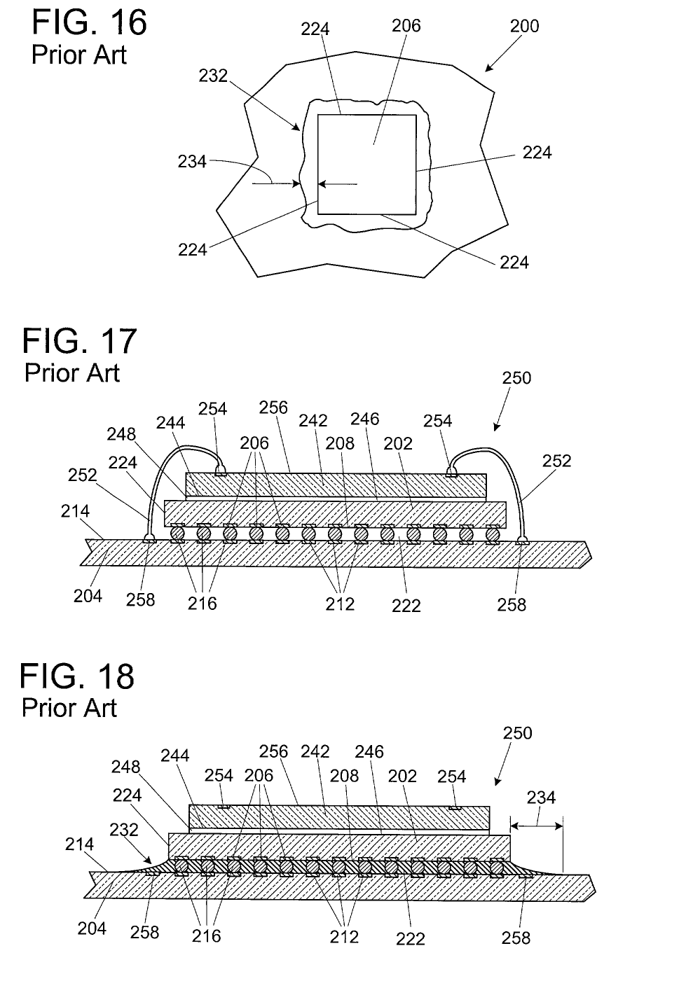

Although inverting the resulting structure, as shown in FIG. 4, and performing the fabrication steps of FIGS. 5 and 6, it is not necessary. As shown in FIG. 8, the underfill dispensing tool 122 may be positioned in or proximate to the through-hole 108 without inversion and the underfill material 124 is dispensed through the underfill dispensing tool 122 and into the through-hole 108. Capillary action distributes the underfill material 124 substantially evenly around the conductive bumps 114 and forms the fillet 126 proximate edges 128 of the microelectronic die 112. Again, it is preferred that a predetermined amount of underfill material 124 be used.

As it will be evident to those skilled in the art, the size of the through-hole 108 is preferably optimized based on a number of variables including, but not limited to, the size of the microelectronic die 112, the underfill material 124 rheology, the size of any filler particles used in the underfill material 124, and the size of the underfill dispensing tool 122. Furthermore, although the through-hole 108 is illustrated as being positioned proximate the position of the center of the microelectronic die 112, its position can be varied or optimized depending on the size and pattern of conductive bumps 114 to optimize the flow pattern of the underfill material 124.

FIGS. 8-10 illustrate the formation of a stacked microelectronic device. FIG. 8 illustrates an intermediate structure 140 comprising a substrate 134 having a through-hole 108 and microelectronic die 112 attached to an active surface 136 thereof, as well as an underfill material 124 disposed between the substrate 134 and the microelectronic die 112 and cured as described in FIGS. 5-7. The substrate 134 also includes at least one wirebond land 132 on an active surface 136 thereof.

FIG. 9 illustrates a second microelectronic die 142 attached by its back surface 146 to a back surface 144 of the microelectronic die 112 with a layer of adhesive 148. As shown in FIG. 10, a plurality of wirebonds 158 makes electrical contact between lands 152 on an active surface 154 of the second microelectronic die 142 and wirebond lands 132 on the substrate 134 to form the stacked microelectronic device 160. Preferably, the underfill material 124 is cured prior to the attachment of the second microelectronic die 142. Furthermore, it is understood that the underfill material 124 may be disposed and cured after the attachment of the second microelectronic die 142.

It is, of course, understood that additional steps and fabrication could be undertaken, including mold/encapsulation of the packages of FIGS. 7 and 10, attachment of heat dissipation devices, and the formation of multi-stack packages.

Having thus described in detail embodiments of the present invention, it is understood that the invention defined by the appended claims is not to be limited by particular details set forth in the above description, as many apparent variations thereof are possible without departing from the spirit or scope thereof.

What is claimed is:

1. A method of fabricating a microelectronic package, comprising:
providing a substrate having a first surface, an opposing second surface, and a plurality of lands disposed on said first surface;
forming a through-hole extending from said substrate first surface to said substrate second surface;
providing a microelectronic die having an active surface, a back surface, and a plurality of pads disposed on said active surface in a corresponding relationship to said plurality of substrate lands;
electrically attaching said plurality of substrate lands to said plurality of corresponding microelectronic die pads with a plurality of conductive bumps;
disposing an underfill material through said through-hole such that said underfill material is dispersed between said microelectronic die active surface and said substrate first surface.

2. The method of claim 1, wherein forming said through-hole comprises forming said through-hole by at least one of the methods consisting of drilling, laser ablation, and etching.

3. The method of claim 1, wherein disposing said underfill material comprises positioning an underfill material dispensing device proximate said through-hole and injecting said underfill material into said through-hole.

4. The method of claim 1, wherein positioning said underfill material dispensing device proximate said through-hole comprises positioning a dispensing needle proximate said through-hole.

5. The method of claim 1, wherein disposing said underfill material comprises disposing an epoxy material.

6. The method of claim 1, further including curing said underfill material.

7. A method of fabricating a microelectronic package, comprising:
providing a substrate having a first surface, an opposing second surface, and a plurality of lands disposed on said first surface;
forming a through-hole extending from said substrate first surface to said substrate second surface;
providing a microelectronic die having an active surface, a back surface, and a plurality of pads disposed on said active surface in a corresponding relationship to said plurality of substrate lands;
electrically attaching said plurality of substrate lands to said plurality of corresponding microelectronic die pads with a plurality of conductive bumps;
positioning said microelectronic die and said substrate such that said microelectronic die is gravitationally below said substrate; and
disposing an underfill material through said through-hole such that said underfill material is dispersed between said microelectronic die active surface and said substrate first surface.

8. The method of claim 7, wherein forming said through-hole comprises forming said through-hole by at least one of the methods consisting of drilling, laser ablation, and etching.

9. The method of claim 7, wherein disposing said underfill material comprises positioning an underfill material dispensing device proximate said through-hole and injecting said underfill material into said through-hole.

10. The method of claim 9, wherein positioning said underfill material dispensing device proximate said through-hole comprises positioning a dispensing needle proximate said through-hole.

11. The method of claim 7, wherein disposing said underfill material comprises disposing an epoxy material.

12. The method of claim 7, further including curing said underfill material.

13. A method of fabricating a microelectronic package, comprising:
providing a substrate having a first surface, an opposing second surface, a plurality of lands disposed on said first surface, and at least one wirebond land on said first surface;
forming a through-hole extending from said substrate first surface to said substrate second surface;
providing a microelectronic die having an active surface, a back surface, and a plurality of pads disposed on said active surface in a corresponding relationship to said plurality of substrate lands;
electrically attaching said plurality of substrate lands to said plurality of corresponding microelectronic die pads with a plurality of conductive bumps;
disposing an underfill material through said through-hole such that said underfill material is dispersed between said microelectronic die active surface and said substrate first surface;
providing a second microelectronic die having an active surface, a back surface, and at least one wirebond pad disposed on said active surface;
attaching said second microelectronic die back surface to said microelectronic die back surface; and
attaching at least one wirebond between said at least one substrate wirebond land and said second microelectronic die wirebond pad.

14. The method of claim 13, wherein forming said through-hole comprises forming said through-hole by at least one of the methods consisting of drilling, laser ablation, and etching.

15. The method of claim 13, wherein disposing said underfill material comprises positioning an underfill material dispensing device proximate said through-hole and injecting said underfill material into said through-hole.

16. The method of claim 15, wherein positioning said underfill material dispensing device proximate said through-hole comprises positioning a dispensing needle proximate said through-hole.

17. The method of claim 13, wherein disposing said underfill material comprises disposing an epoxy material.

18. The method of claim 13, further including curing said underfill material.

19. The method of claim 13, wherein said attaching said second microelectronic die back surface to said microelectronic die back surface comprises disposing a layer of adhesive therebetween.

20. The method of claim 13, wherein further including positioning said microelectronic die and said substrate such that said microelectronic die is gravitationally below said substrate prior to disposing said underfill material.
